(19) United States
(12) Patent Application Publication
(10) Pub. No.: US 2008/0263415 A1
(43) Pub. Date: Oct. 23, 2008

(54) Integrated Circuit, Memory Module, Method of Operating an Integrated Circuit, Method of Fabricating an Integrated Circuit, Computer Program Product, and Computing System

(76) Inventors: Bernhard Ruf, Sauerlach (DE); Michael Kund, Tuntenhausen (DE); Heinz Hoenigschmid, Poecking (DE)

Correspondence Address: SLATER & MATSIL, L.L.P., 17950 PRESTON ROAD, SUITE 1000, DALLAS, TX, 75252, US

(21) Appl. No.: 11/736,382

(22) Filed: Apr. 17, 2007

(51) Int. Cl. G11C 29/00

(52) U.S. Cl. 714/721

(57) ABSTRACT

According to one embodiment of the present invention, an integrated circuit includes a plurality of memory cells, the integrated circuit being operable in a memory cell testing mode in which testing signals are applied to the memory cells, wherein the strengths and durations of the testing signals at least partly differ from the strengths and durations of programming signals or sensing signals used for programming and sensing memory states of the memory cells.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of a solid electrolyte memory device set to a first memory state;

FIG. 1B shows a cross-sectional view of a solid electrolyte memory device set to a second memory state;

FIG. 2A shows a top view of an integrated circuit according to one embodiment of the present invention;

FIG. 2B shows a top view of an integrated circuit according to one embodiment of the present invention;

FIG. 2C shows a top view of an integrated circuit according to one embodiment of the present invention;

FIG. 2D shows a top view of an integrated circuit according to one embodiment of the present invention;

FIG. 2E shows a top view of an integrated circuit according to one embodiment of the present invention;

FIG. 2F shows a top view of an integrated circuit according to one embodiment of the present invention;

FIG. 3 shows a flow chart of a method of operating an integrated circuit according to one embodiment of the present invention;

FIG. 4 shows a flow chart of a method of manufacturing an integrated circuit according to one embodiment of the present invention;

FIG. 5 shows a computing system according to one embodiment of the present invention;

FIG. 6A shows a cross-sectional view of a first processing stage of a method of manufacturing an integrated circuit according to one embodiment of the present invention;

FIG. 6B shows a cross-sectional view of a second processing stage of a method of manufacturing an integrated circuit according to one embodiment of the present invention;

FIG. 6C shows a cross-sectional view of a third processing stage of a method of manufacturing an integrated circuit according to one embodiment of the present invention;

FIG. 6D shows a cross-sectional view of a fourth processing stage of a method of manufacturing an integrated circuit according to one embodiment of the present invention;

FIG. 6E shows a cross-sectional view of a fifth processing stage of a method of manufacturing an integrated circuit according to one embodiment of the present invention;

FIG. 7A shows a memory module according to one embodiment of the present invention;

FIG. 7B shows a stacked memory module according to one embodiment of the present invention;

FIG. 8 shows a cross-sectional view of a phase changing memory cell;

FIG. 9 shows a schematic drawing of an integrated circuit;

FIG. 10A shows a cross-sectional view of a carbon memory cell set to a first switching state;

FIG. 10B shows a cross-sectional view of a carbon memory cell set to a second switching state;

FIG. 11A shows a schematic drawing of a resistivity changing memory cell; and

FIG. 11B shows a schematic drawing of a resistivity changing memory cell.

### DETAILED DESCRIPTION OF ILLUSTRATIVE EMBODIMENTS

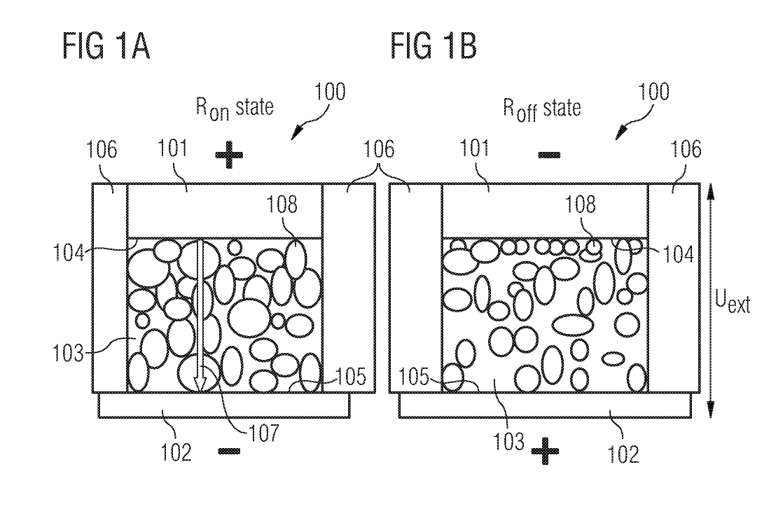

Since the embodiments of the present invention can be applied to programmable metallization cell devices (PMC) (e.g., solid electrolyte devices like CBRAM (conductive bridging random access memory) devices), in the following description, making reference to FIGS. 1A and 1B, a basic principle underlying embodiments of CBRAM devices will be explained.

As shown in FIG. 1A, a CBRAM cell 100 includes a first electrode 101 a second electrode 102, and a solid electrolyte block (in the following also referred to as ion conductor block) 103 which includes the active material and which is sandwiched between the first electrode 101 and the second electrode 102. This solid electrolyte block 103 can also be shared between a large number of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu) or zink (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor 103 may, for example, range between 5 nm and 500 nm. The thickness of the first electrode 101 may, for example, range between 10 nm and 100 nm. The thickness of the second electrode 102 may, for example, range between 5 nm and 500 nm, between 15 nm to 150 nm, or between 25 nm and 100 nm. It is to be understood that the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example, arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. In the case where a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107. After having applied the voltage/inverse voltage, the memory cell 100 remains within the corresponding defined switching state even if the voltage/inverse voltage has been removed.

In order to determine the current memory status of a CBRAM cell, for example a sensing current is routed through the CBRAM cell. The sensing current experiences a high resistance in case no conductive bridge 107 exists within the CBRAM cell, and experiences a low resistance in case a conductive bridge 107 exists within the CBRAM cell. A high resistance may for example represent “0”, whereas a low resistance represents “1”, or vice versa. The memory status detection may also be carried out using sensing voltages.

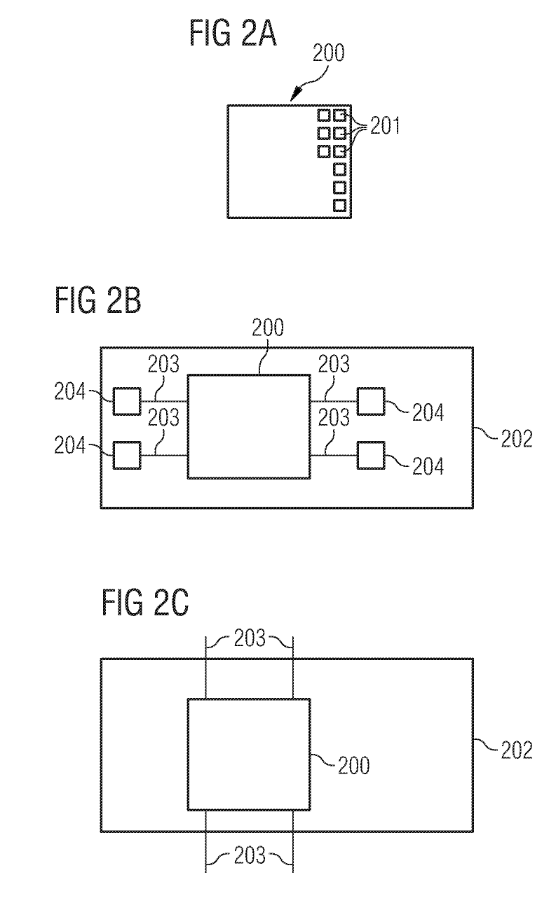

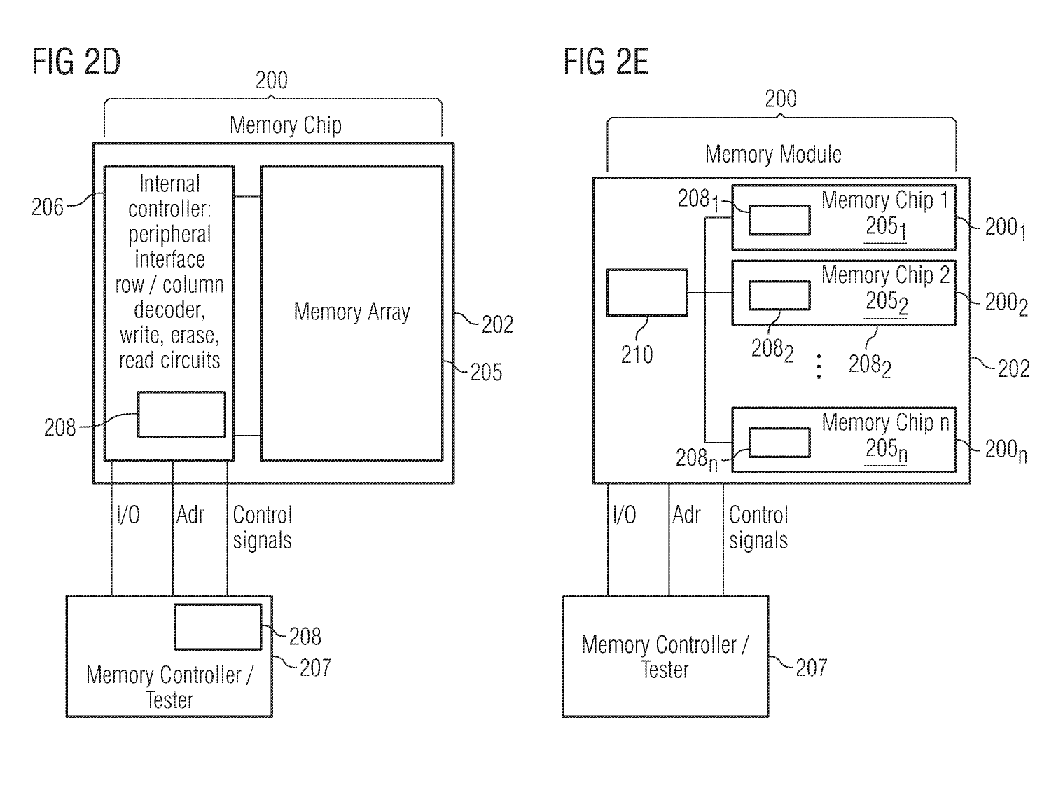

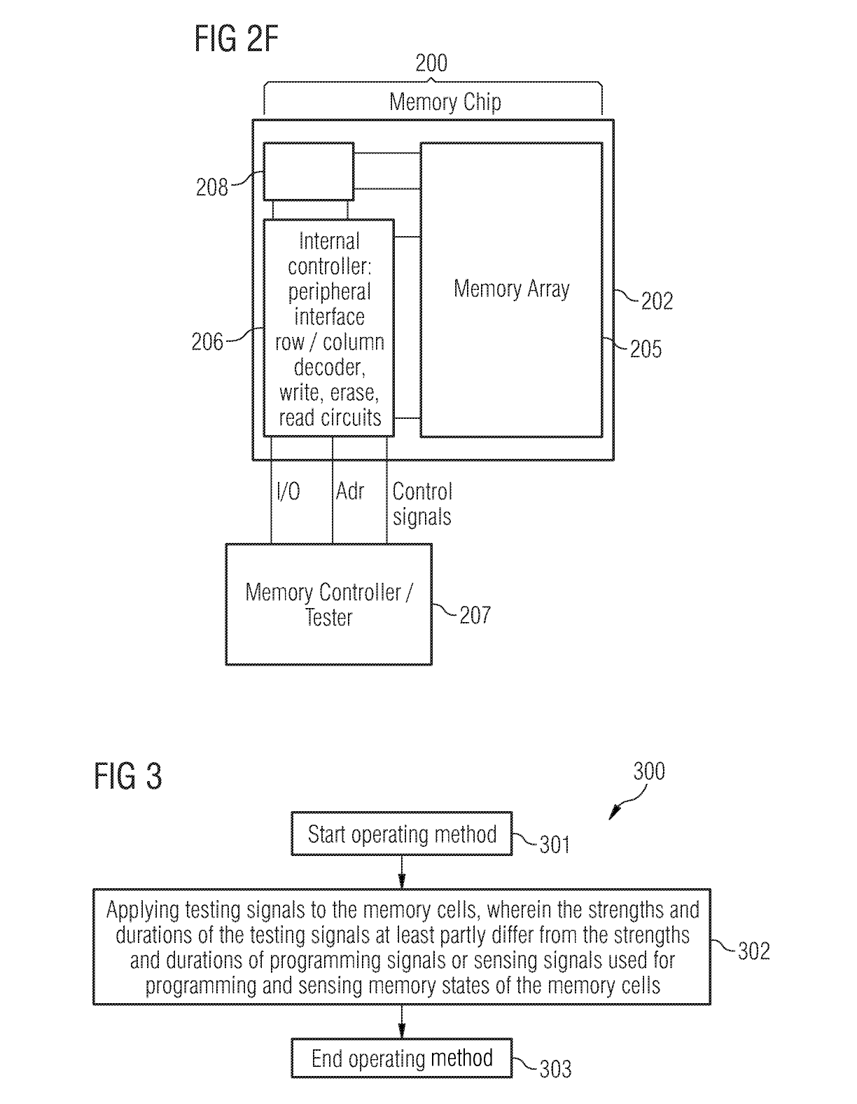

FIG. 2A shows an integrated circuit 200 including a plurality of memory cells 201. The integrated circuit 200 is operable in a memory cell testing mode in which testing signals are applied to the memory cells 201. The strengths and durations of the testing signals at least partially differ from the strengths and durations of programming signals or sensing signals used for programming and sensing memory states of the memory cells 201.

The use of testing signal strengths and testing signal durations which do not comply with testing signal strengths and testing signal durations normally used when programming or sensing the memory states of the memory cells 201, inter alia, makes it possible to carry out testing procedures which would not be possible using only “normal” programming signals/sensing signals. By way of example, extremely high strengths of programming signals may be used for testing, thereby forcing the memory cells 201 to operate under extreme, non-standard compliant conditions. Since it is more likely that defect memory cells show their defectness under extreme conditions rather than under normal conditions, the integrated circuit according to this embodiment makes it easier to detect defective memory cells 201 (the defect memory cells 201 are “forced” to show their defectiveness).

As shown in FIGS. 2B, 2C, and to 2D, the integrated circuit 200 may be surrounded by a circuit housing 202.

As shown in FIGS. 2B, 2C, the integrated circuit 200 may be connected to testing terminals 203 which receive testing signals being generated outside the integrated circuit 200 or which receive triggering signals which are generated outside the integrated circuit 200, and which trigger the integrated circuits 200 to generate testing signals.

In the embodiment shown in FIG. 2B, the testing terminals 203 are completely located inside the circuit housing 202, whereas in the embodiment shown in FIG. 2C, the testing terminals 203 are at least partly located outside the circuit housing 202. In the embodiment shown in FIG. 2B, the testing terminals 203 are connected to testing pads 204 which facilitate to supply testing signals/triggering signals generated outside the circuit housing 202 to the integrated circuits 200. An effect of the embodiment shown in FIG. 2B is that a user of the integrated circuit 200 is not able to supply testing signals via the testing terminals 203 to the integrated circuit 200 since the testing terminals 203 are hidden within the circuit housing 202. Thus, it can be ensured that the integrated circuit 200 is not destroyed by testing signals/triggering signals which do not comply with corresponding testing signal/triggering signal requirements.

In the embodiment shown in FIG. 2C, since the testing terminals 203 are accessible to the user, the user is capable of performing testing procedures of the integrated circuits on its own by supplying testing signals/triggering signals via the testing terminals 203 to the integrated circuits 200.

In the embodiment shown in FIG. 2D, the integrated circuit 200 includes a memory cell array 205 and a memory controller 206 coupled to the memory cell array 205. In this embodiment, testing functionality 208 of the integrated circuits 200 for testing the memory cells 201 is located within the memory controller 206. Additionally, testing functionality 208 of the integrated circuit for testing the memory cells is located within a memory controller 207 located outside the circuit housing 202 (which may also be omitted).

FIG. 2E shows an embodiment where the integrated circuit 200 (which may be interpreted as an integrated circuit module) is split into n integrated circuit units 200₁ to 200ₙ, wherein each integrated circuit unit 200₁ to 200ₙ includes one of n testing functionality units 208₁ to 208ₙ and one of n memory cell array units 205₁ to 205ₙ. Further, testing functionality 208 which is connected to all integrated circuit units 200₁ to 200ₙ is provided outside the integrated circuit units 200₁ to 200ₙ, however inside the circuit housing 202.

FIG. 2F shows an embodiment which is similar to the embodiment shown in FIG. 2D. However, the testing functionality 208 is located outside the memory controller 206, however inside the circuit housing 202. Further, no testing functionality 208 is located within the memory controller 207.

Embodiments of the invention can be applied to integrated circuits including arbitrary types of memory cells, for example, resistivity changing memory cells (for example, solid electrolyte memory cells (CBRAM cells), magneto resistive memory cells (MRAM cells), phase changing memory cells (PCRAM cells), organic memory cells (ORAM cells), or dynamic random access memory cells (DRAM cells)).

According to one embodiment of the present invention, the memory cells 201 include resistivity changing memory cells, wherein a select device is assigned to each resistivity changing memory cell. According to one embodiment of the invention, testing functionality 208 for testing the memory cells 201 is operable such that the resistivity changing memory cells 201 are simultaneously set to a common resistance value by applying respective testing voltages or testing currents to the resistivity changing memory cells 201. For example, their resistivity changing memory cells may be set to a common resistance value by applying a constant testing current or constant testing voltage to each resistivity changing memory cell 201 for a period of time which is significantly larger than the period of time used for reading or programming the memory states of the resistivity changing memory cells 201. In this case, the resistance value of the resistivity changing memory cells 201 may be controlled by using the select devices as voltage dividers. In other words, the testing functionality 208 is used for testing the resistivity changing memory cells 201 in a non-standard way (the testing signals have strengths and durations which are not used during normal operation of the integrated circuit 200).

An embodiment of the invention further provides a means for testing a memory means, the means for testing being operable in a memory means testing mode in which testing signals are applied to the memory means, wherein the strengths and durations of the testing signals at least partially differ from the strengths and durations of programming signals or sensing signals used for programming and sensing memory states of the memory means.

The means for testing may be a circuit means and may, for example, be an integrated circuit, the memory means may, for example, be memory cells like resistivity changing memory cells (e.g., CBRAM cells, MRAM cells, PCRAM cells or ORAM cells).

An embodiment of the invention further provides a memory module including at least one integrated circuit or circuit means according to one embodiment of the invention. According to one embodiment of the invention, the memory module is stackable.

FIG. 3 shows a method 300 of operating an integrated circuit including a plurality of memory cells according to one embodiment of the invention.

At 301, the operating method is started.

At 302, testing signals are applied to the memory cells, wherein the strengths and durations of the testing signals at least partially differ from the strengths and durations of programming signals or sensing signals used for programming and sensing memory states of the memory cells.

At 303, the method is terminated.

According to one embodiment of the invention, 302 includes the generation of testing signals outside the integrated circuit which are then supplied to the integrated circuit.

According to one embodiment of the invention, 302 includes the supplying triggering signals triggering the integrated circuit in order to generate testing signals to the integrated circuit.

According to one embodiment of the invention, the memory cells include resistivity changing memory cells, wherein a select device is assigned to each resistivity changing memory cell. In this case, 302 may include simultaneously setting resistivity changing memory cells to a common resistance value by applying respective testing voltages or testing currents to the resistivity changing memory cells. The resistivity changing memory cells may be set to a common resistance value by applying a constant testing current or constant testing voltage to each resistivity changing memory cell for a period of time which is significantly larger than the period of time used for reading and programming the memory states of the resistivity changing memory cells. According to one embodiment of the present invention, the period of time for applying a constant testing current or constant testing voltage is 100 μs up to 100 ms. In contrast, according to one embodiment of the present invention, the period of time used for reading or programming the states of the cells is 10 ns up to 10 μs. According to one embodiment of the present invention, testing voltages used are about 500 mV. They may, for example, be used in combination with testing durations of 10 ms.

The resistance value of the resistivity changing memory cells may be controlled by using the select devices as voltage dividers.

According to one embodiment of the invention, a method of operating a plurality of memory cells is provided. The method includes applying testing signals to the memory cells, wherein the strengths and durations of the testing signals at least partially differ from the strengths and durations of programming signals or sensing signals used for programming and sensing memory states of the memory cells.

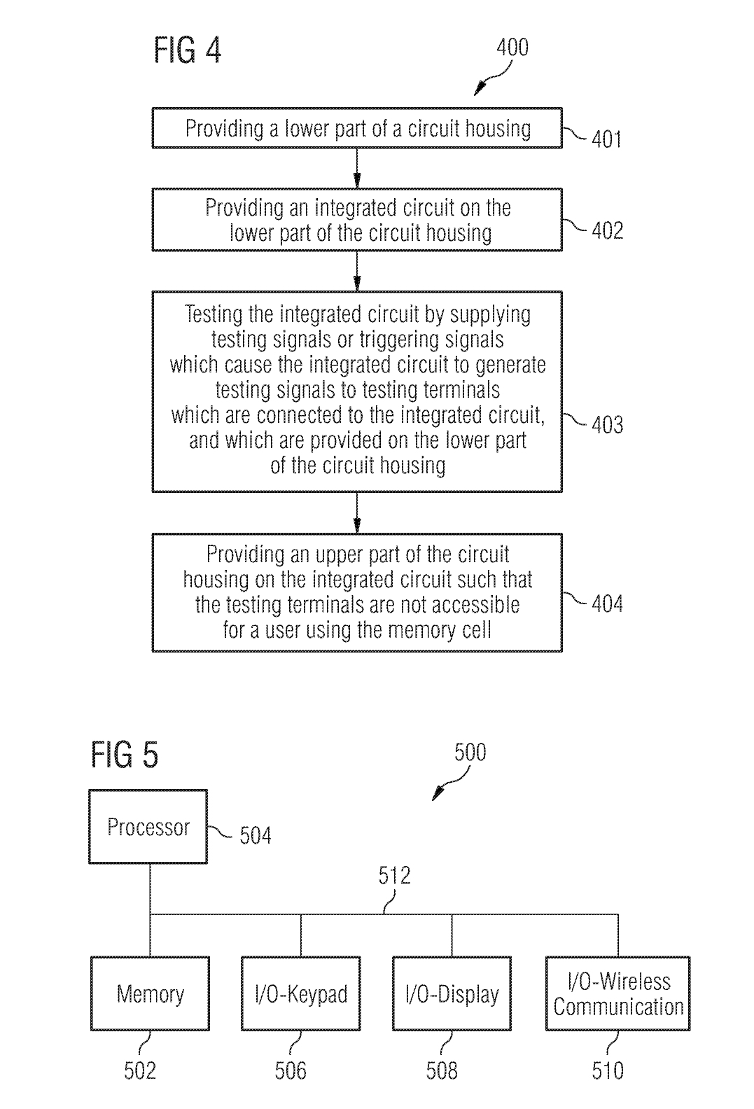

FIG. 4 shows a method 400 of manufacturing an integrated circuit including a plurality of memory cells.

At 401, a lower part of a circuit housing is provided.

At 402, an integrated circuit is provided on or above the lower part of the circuit housing.

At 403, the integrated circuit is tested by supplying testing signals or triggering signals which cause the integrated circuit to generate testing signals to testing terminals which are connected to the integrated circuit, and which are provided on the lower part of the circuit housing.

At 404, an upper part of the circuit housing is provided on or above the integrated circuit such that the testing terminals are not accessible for a user using the integrated circuit.

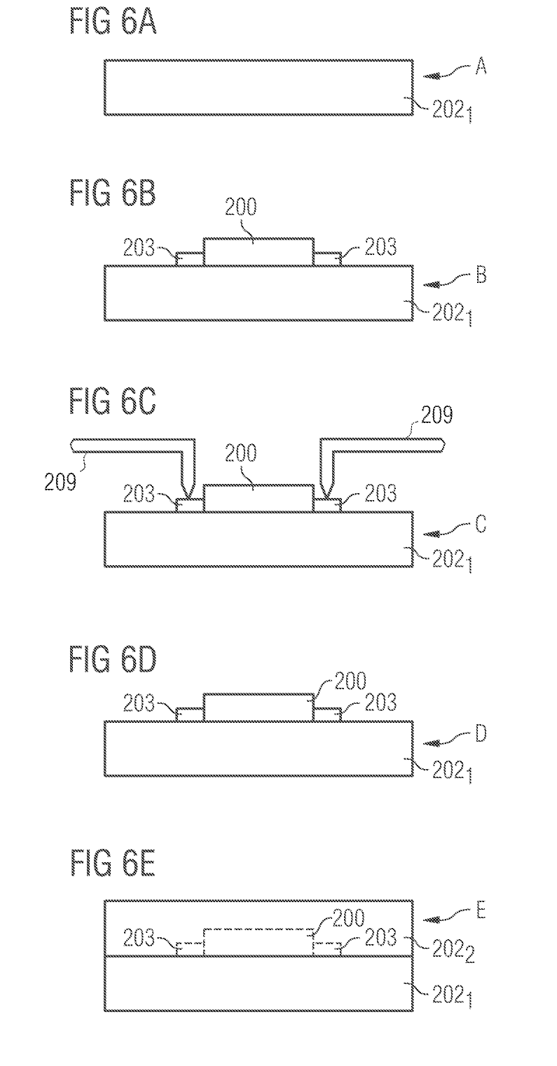

An example of the method 400 of manufacturing an integrated circuit will be explained in the following description making reference to FIG. 6A to 6E.

FIG. 6A shows a manufacturing stage A in which a lower part 202₁ of a circuit housing has been provided. FIG. 6B shows a manufacturing stage B in which an integrated circuit 200 has been provided on the lower part 202₁ of the circuit housing. Further, testing terminals 203 which are connected to the integrated circuit 200 are provided on the lower part 202₁ of the circuit housing. FIG. 6C shows a manufacturing stage C in which the integrated circuit 200 is tested by supplying testing signals or triggering signals which cause the integrated circuit to generate testing signals to the testing terminals 203. The testing signals/triggering signals are supplied via conductive lines 209 to the testing terminals 203. After having tested the integrated circuit 200 the conductive lines 209 are removed (manufacturing stage D shown in FIG. 6D). FIG. 6E shows a processing stage E in which an upper part 202₂ of the circuit housing has been provided on the lower part 202₁ of the circuit housing such that the integrated circuit 200 is encapsulated by the lower part 202₁ and the upper part 202₂ of the circuit housing.

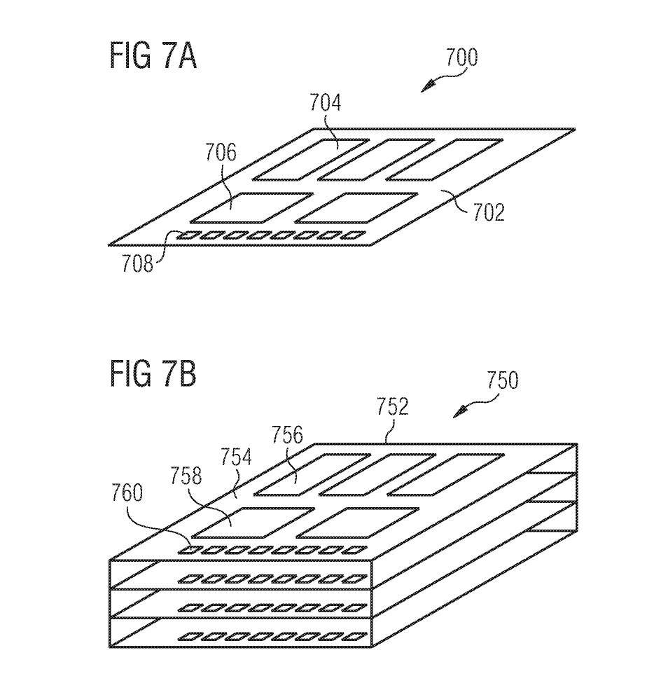

As shown in FIGS. 7A and 7B, in some embodiments, memory devices such as those described herein may be used in modules.

In FIG. 7A, a memory module 700 is shown, on which one or more integrated circuits, circuit means or memory cells 704 are arranged on a substrate 702. The integrated circuits/circuit means/memory cells 704 may include numerous memory cells in accordance with an embodiment of the invention. The memory module 700 may also include one or more electronic devices 706, which may include memory, processing circuitry, control circuitry, addressing circuitry, bus interconnection circuitry, or other circuitry or electronic devices that may be combined on a module with a memory device, such as the integrated circuits/circuit means/memory cells 704. Additionally, the memory module 700 includes multiple electrical connections 708, which may be used to connect the memory module 700 to other electronic components, including other modules.

As shown in FIG. 7B, in some embodiments, these modules may be stackable, to form a stack 750. For example, a stackable memory module 752 may contain one or more memory devices 756, arranged on a stackable substrate 754. The memory device 756 contains memory cells that employ memory elements in accordance with an embodiment of the invention. The stackable memory module 752 may also include one or more electronic devices 758, which may include memory, processing circuitry, control circuitry, addressing circuitry, bus interconnection circuitry, or other circuitry or electronic devices that may be combined on a module with a memory device, such as the memory device 756. Electrical connections 760 are used to connect the stackable memory module 752 with other modules in the stack 750, or with other electronic devices. Other modules in the stack 750 may include additional stackable memory modules, similar to the stackable memory module 752 described above, or other types of stackable modules, such as stackable processing modules, control modules, communication modules, or other modules containing electronic components.

In accordance with some embodiments of the invention, integrated circuits, memory devices, memory cells or memory elements as described herein may be used in a variety of applications or systems, such as the illustrative computing system shown in FIG. 5. The computing system 500 includes an integrated circuit/memory device 502, which may include resistivity changing memory cells like carbon memory cells as described hereinabove. The system also includes a processing apparatus 504, such as a microprocessor or other processing device or controller, as well as input and output apparatus, such as a keypad 506, display 508, and/or wireless communication apparatus 510. The integrated circuit/memory device 502, processing apparatus 504, keypad 506, display 508 and wireless communication apparatus 510 are interconnected by a bus 512.

The wireless communication apparatus 510 may have the ability to send and/or receive transmissions over a cellular telephone network, a WiFi wireless network, or other wireless communication network. It will be understood that the various input/output devices shown in FIG. 5 are merely examples. Memory devices including memory cells in accordance with embodiments of the invention may be used in a variety of systems. Alternative systems may include a variety input and output devices, multiple processors or processing apparatus, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied. The computing system 500 may, for example, be an electronic testing system comprising a control circuitry, at least one input device coupled to said control circuitry, at least one output device coupled to said control circuitry, and an integrated circuit according to one embodiment of the present invention coupled to said control circuitry.

According to one embodiment of the invention, the resistivity changing (memory) cells are phase changing (memory) cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may be routed through the phase changing material (or a sensing voltage may be applied across the phase changing material), thereby sensing the resistance of the resistivity changing memory cell, which represents the memory state of the memory cell.

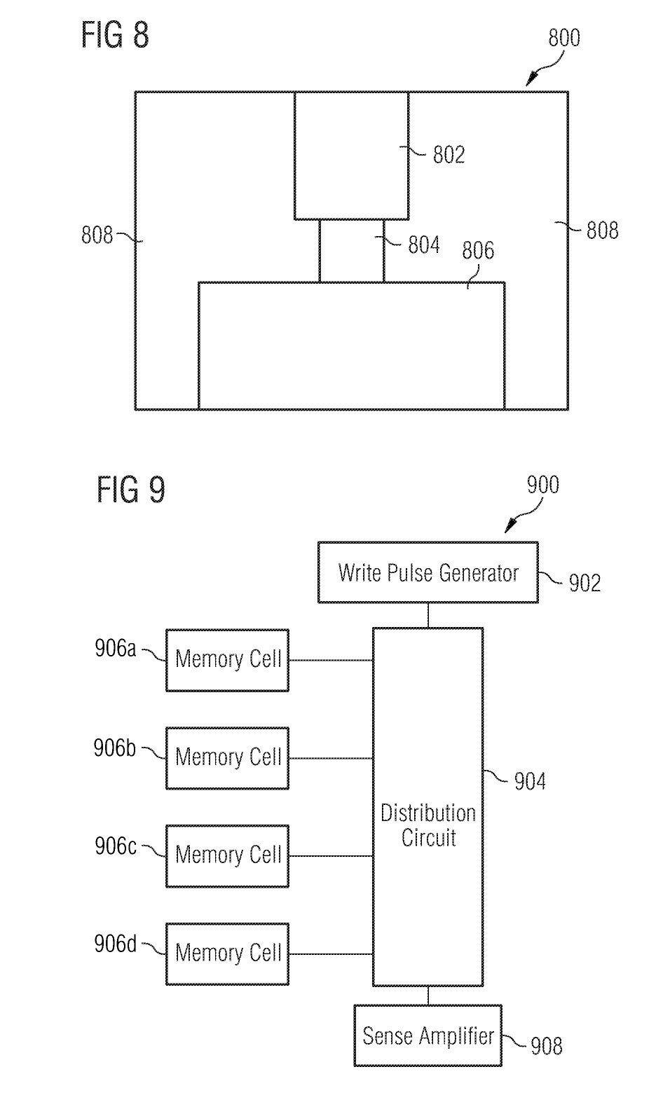

FIG. 8 illustrates a cross-sectional view of an exemplary phase changing memory cell 800 (active-in-via type). The phase changing memory cell 800 includes a first electrode 802, a phase changing material 804, a second electrode 806, and an insulating material 808. The phase changing material 804 is laterally enclosed by the insulating material 808. To use the phase changing memory cell in a memory cell, a selection device (not shown), such as a transistor, a diode, or another active device, may be coupled to the first electrode 802 or to the second electrode 806 to control the application of a current or a voltage to the phase changing material 804 via the first electrode 802 and/or the second electrode 806. To set the phase changing material 804 to the crystalline state, a current pulse and/or voltage pulse may be applied to the phase changing material 804, wherein the pulse parameters are chosen such that the phase changing material 804 is heated above its crystallization temperature, while keeping the temperature below the melting temperature of the phase changing material 804. To set the phase changing material 804 to the amorphous state, a current pulse and/or voltage pulse may be applied to the phase changing material 804, wherein the pulse parameters are chosen such that the phase changing material 804 is quickly heated above its melting temperature, and is quickly cooled.

The phase changing material 804 may include a variety of materials. According to one embodiment, the phase changing material 804 may include or consist of a chalcogenide alloy that includes one or more cells from group VI of the periodic table. According to another embodiment, the phase changing material 804 may include or consist of a chalcogenide compound material, such as GeSbTe, SbTe, GeTe or AgInSbTe. According to a further embodiment, the phase changing material 804 may include or consist of chalcogen free material, such as GeSb, GaSb, InSb, or GeGaInSb. According to still another embodiment, the phase changing material 804 may include or consist of any suitable material including one or more of the elements Ge, Sb, Te, Ga, Bi, Pb, Sn, Si, P, O, As, In, Se, and S.

According to one embodiment, at least one of the first electrode 802 and the second electrode 806 may include or consist of Ti, V, Cr, Zr, Nb, Mo, Hf, Ta, W, or mixtures or alloys thereof. According to another embodiment, at least one of the first electrode 802 and the second electrode 806 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

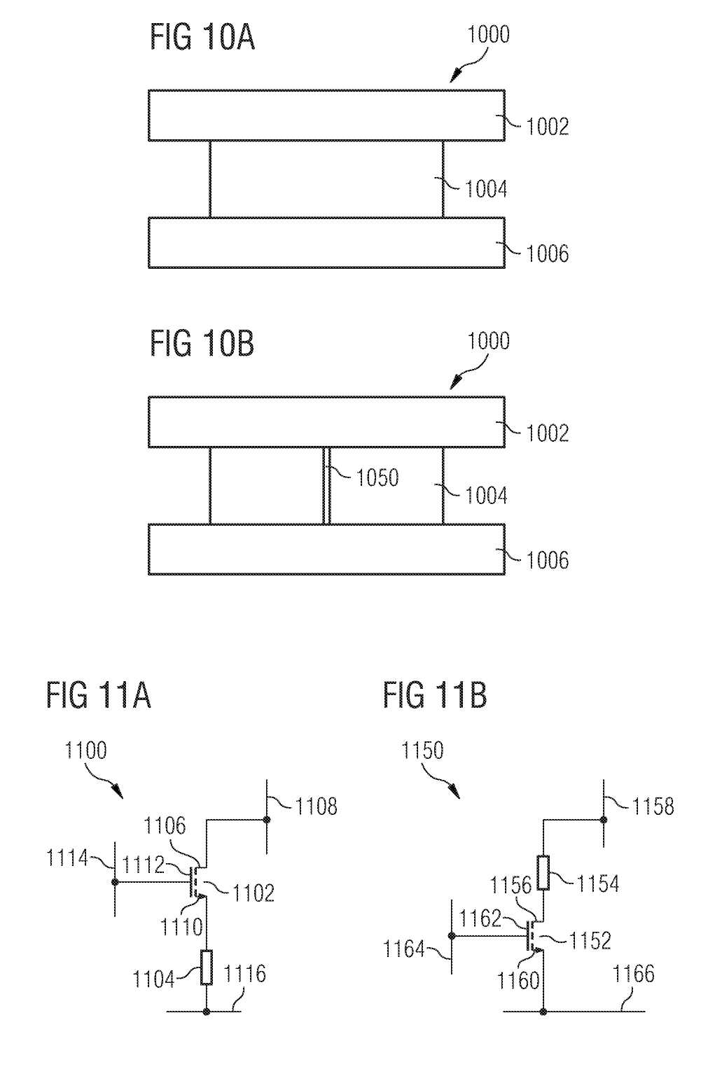

FIG. 9 illustrates a block diagram of a memory device 900 including a write pulse generator 902, a distribution circuit 904, phase changing memory cells 906a, 906b, 906c, 906d (for example phase changing memory cells 1000 as shown in FIG. 10), and a sense amplifier 908. According to one embodiment, a write pulse generator 902 generates current pulses or voltage pulses that are supplied to the phase changing memory cells 906a, 906b, 906c, 906d via the distribution circuit 904, thereby programming the memory states of the phase changing memory cells 906a, 906b, 906c, 906d. According to one embodiment, the distribution circuit 904 includes a plurality of transistors that supply direct current pulses or direct voltage pulses to the phase changing memory cells 906a, 906b, 906c, 906d or to heaters being disposed adjacent to the phase changing memory cells 906a, 906b, 906c, 906d.

As already indicated, the phase changing material of the phase changing memory cells 906a, 906b, 906c, 906d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 908 is capable of determining the memory state of one of the phase changing memory cells 906a, 906b, 906c, or 906d in dependence on the resistance of the phase changing material.

To achieve high memory densities, the phase changing memory cells 906a, 906b, 906c, 906d may be capable of storing multiple bits of data, i.e., the phase changing material may be programmed to more than two resistance values. For example, if a phase changing memory cell 906a, 906b, 906c, 906d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 9 may also be applied in a similar manner to other types of resistivity changing memory cells like programmable metallization cells (PMCs), magento-resistive memory cells (e.g., MRAMs), organic memory cells (e.g., ORAMs), or transition metal oxide cells (TMOs).

Another type of resistivity changing (memory) cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced phase change between an sp³-rich phase and an sp²-rich phase may be used to change the resistivity of an amorphous carbon material. These differing resistivities may be used to represent different memory states. For example, a high resistance sp³-rich phase can be used to represent a “0”, and a low resistance sp²-rich phase can be used to represent a “1”. It will be understood that intermediate resistance states may be used to represent multiple bits, as discussed above.

Generally, in this type of carbon memory cell, application of a first temperature causes the conversion of high resistivity sp³-rich amorphous carbon to relatively low resistivity sp²-rich amorphous carbon. This conversion can be reversed by application of a second temperature, which is generally higher than the first temperature. As discussed above, these temperatures may be provided, for example, by applying a current and/or voltage pulse to the carbon material. Alternatively, the temperatures can be provided by using a resistive heater which is disposed adjacent to the carbon material.

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 10A and 10B.

FIG. 10A shows a carbon memory cell 1000 that includes a top contact 1002, a carbon storage layer 1004 including an insulating amorphous carbon material rich in sp³-hybridized carbon atoms, and a bottom contact 1006. As shown in FIG. 10B, by forcing a current (or voltage) through the carbon storage layer 1004, an sp² filament 1050 can be formed in the sp³-rich carbon storage layer 1004, changing the resistivity of the memory cell. Application of a current (or voltage) pulse with higher energy (or, in some embodiments, reversed polarity) may destroy the sp² filament 1050, increasing the resistance of the carbon storage layer 1004. As discussed above, these changes in the resistance of the carbon storage layer 1004 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may include a transistor, diode, or other active component for selecting the memory cell. FIG. 11A shows a schematic representation of such a memory cell that uses a resistivity changing memory element. The memory cell 1100 includes a select transistor 1102 and a resistivity changing memory cell 1104. The select transistor 1102 includes a source 1106 that is connected to a bit line 1108, a drain 1110 that is connected to the memory element 1104, and a gate 1112 that is connected to a word line 1114. The resistivity changing memory element 1104 also is connected to a common line 1116, which may be connected to ground, or to other circuitry, such as circuitry (not shown) for determining the resistance of the memory cell 1100, for use in reading. Alternatively, in some configurations, circuitry (not shown) for determining the state of the memory cell 1100 during reading may be connected to the bit line 1108. It should be noted that as used herein the terms connected and coupled are intended to include both direct and indirect connection and coupling, respectively.

To write to the memory cell 1100, the word line 1114 is used to select the memory cell 1100, and a current (or voltage) pulse on the bit line 1108 is applied to the resistivity changing memory element 1104, changing the resistance of the resistivity changing memory element 1104. Similarly, when reading the memory cell 1100, the word line 1114 is used to select the cell 1100, and the bit line 1108 is used to apply a reading voltage (or current) across the resistivity changing memory element 1104 to measure the resistance of the resistivity changing memory element 11104.

The memory cell 1100 may be referred to as a 1T1J cell, because it uses one transistor, and one memory junction (the resistivity changing memory element 1104). Typically, a memory device will include an array of many such cells. It will be understood that other configurations for a 1T1J memory cell, or configurations other than a 1T1J configuration may be used with a resistivity changing memory element. For example, in FIG. 11B, an alternative arrangement for a 1T1J memory cell 1150 is shown, in which a select transistor 1152 and a resistivity changing memory element 1154 have been repositioned with respect to the configuration shown in FIG. 11A. In this alternative configuration, the resistivity changing memory element 1154 is connected to a bit line 1158, and to a source 1156 of the select transistor 1152. A drain 1160 of the select transistor 1152 is connected to a common line 1166, which may be connected to ground, or to other circuitry (not shown), as discussed above. A gate 1162 of the select transistor 1152 is controlled by a word line 1164.

According to one embodiment of the present invention, the resistivity changing memory cells are transition metal oxide (TMO) memory cells.

According to one embodiment of the invention, a computer program product is provided, configured to perform, when being carried out on a computing device, a method according to any embodiment of the present invention. An embodiment of the invention further provides a data carrier configured to store a computer program product according to one embodiment of the invention.

In the following description, further aspects of exemplary embodiments of the present invention will be explained.

Resistive memory devices like CBRAM devices, PCRAM devices or MRAM devices can adopt different electrical resistance states. In the simplest case (1 bit cell) two resistance states can be adopted which will be referred to in the following as Rₒₙ (low resistance state) and as R_{off} (high resistance state). More generally, in the case of a n bit cell (also referred to as multilevel cell (MLC)), 2ⁿ states can be adopted. Using suitable stimulation, it is possible to cause transitions between different resistance states.

According to one embodiment of the present invention, the testing time of an integrated circuit/memory device is optimized, the failure rate of the integrated circuit/memory device at the user is minimized, and the exploitation rate is increased.

According to one embodiment of the present invention, a “normal” operation mode of the CBRAM memory device (or other types of memory devices) has the following properties: it is accessible to the user within the application, i.e., the user can use the operation mode via the memory controller; the operation mode is specified in the corresponding data sheet (specification).

According to one embodiment of the present invention, a special operating mode is used which is not documented and/or which cannot be used by the memory controller at all. This special operating mode of the CBRAM memory device (or other types of memory devices) solves the above-mentioned problems.

It may be possible to operate the memory device “off spec” i.e., a normal documented operating mode may be chosen, and voltages and currents which are lying outside of the corresponding ranges allowed by the specification are chosen, for example. A further possibility are timing irregularities. That is, set up and hold times are chosen which lie outside of the corresponding ranges allowed by the specification. A further possibility is the over timing of the memory device. Embodiments of the invention aim to provoke “weak” cells in order to determine them (in this way, it can, for example, be decided whether the memory device can be sold to a user or not). The over timing further allows the reduction of testing time.

An effect of the approaches described in the last paragraph is that they only provide limited possibilities. For example, it is not possible to selectively influence internal voltages of the memory device. However, this may be necessary in order to selectively provoke particular failure mechanisms. Also, the reduction of testing time is limited when using the above-mentioned approaches.

According to one embodiment of the present invention, one or more special circuits are provided on the chip which are responsible for the special operating modes. In order to trigger different particular operating modes, special control signals may be used. Also, additional (not bonded) pads may be necessary on the chip in order to supply particular voltages or currents or to supply control signals to the integrated circuit. An effect of this embodiment is that the special circuits enable more detailed manipulation possibilities, compared to above-mentioned approaches, and that internal voltages and timings can be changed selectively. Circuits configured for specific purposes may be developed and integrated in dependence on the technology or the testing methods used.

According to one embodiment of the invention, special operating modes of a CBRAM memory device are realized as additional circuits on the memory device. The operating modes may be tailored to individual problems of the technology or of the testing system and allow the optimization of testing procedures (failure detection rates, testing time and failure rate at the user side).

According to one embodiment of the invention, an individual operating mode is provided which is used for simultaneously setting the resistance level of a plurality of memory cells to a resistance level value which has been externally defined.

According to one embodiment of the invention, in order to test the memory device, it is necessary to write a particular resistance level into a part of the memory cells of the memory device. A simple solution is a background in which all memory cells of the memory device are set to the same resistance level (“solid background”). However, also more complex patterns may be used. During “normal” operating mode, each single memory cell has to be addressed and to be programmed. The idea of the special testing mode is that as much as possible memory cells are programmed simultaneously. This saves testing time. Apart from saving testing time, the testing mode externally defines an arbitrary resistance level. This may be used both for initializing of the memory device and for so called signal margin tests. In these tests, “weak” bits (for example, “1” or “0”) are written, in order to provoke failures of weak memory cells, and in order to repair them.

As used herein, the terms “connected” and “coupled” are intended to include both direct and indirect connection and coupling, respectively.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising a plurality of memory cells, the integrated circuit being operable in a memory cell testing mode in which testing signals are applied to the memory cells, wherein strengths and durations of the testing signals at least partly differ from strengths and durations of programming signals or sensing signals used for programming and sensing memory states of the memory cells.

2. The integrated circuit according to claim 1, wherein the integrated circuit is surrounded by a circuit housing.

3. The integrated circuit according to claim 2, wherein the integrated circuit is coupled to testing terminals that receive testing signals being generated outside the integrated circuit, or which receive triggering signals triggering the integrated circuit to generate testing signals.

4. The integrated circuit according to claim 3, wherein the testing terminals are at least partly located outside the circuit housing.

5. The integrated circuit according to claim 3, wherein the testing terminals are completely located inside the circuit housing.

6. The integrated circuit according to claim 2, wherein testing functionality of the integrated circuit for testing the memory cells is at least partly located within a memory controller located within the circuit housing.

7. The integrated circuit according to claim 2, wherein testing functionality of the integrated circuit for testing the memory cells is at least partly located within a memory controller located outside the circuit housing.

8. The integrated circuit according to claim 2, wherein testing functionality of the integrated circuit for testing the memory cells is at least partly located within the circuit housing, however outside a memory controller located inside the circuit housing.

9. The integrated circuit according to claim 1, wherein the memory cells comprise resistivity changing memory cells and wherein a select device is assigned to each resistivity changing memory cell.

10. The integrated circuit according to claim 9, wherein testing functionality of the integrated circuit for testing the memory cells is operable to simultaneously set the resistivity changing memory cells to a common resistance value by applying respective testing voltages or testing currents to the resistivity changing memory cells.

11. The integrated circuit according to claim 10, wherein the resistivity changing memory cells are set to a common resistance value by applying a constant testing current or constant testing voltage to each resistivity changing memory cells for a period of time that is larger than a period of time used for reading or programming the memory states of the resistivity changing memory cells.

12. The integrated circuit according to claim 11, wherein the common resistance value of the resistivity changing memory cells is controlled by using the select devices as a voltage divider.

13. The integrated circuit according to claim 1, wherein the memory cells comprise programmable metallization cells.

14. The integrated circuit according to claim 1, wherein the memory cells comprise solid electrolyte cells.

15. The integrated circuit according to claim 1, wherein the memory cells comprise phase changing cells.

16. The integrated circuit according to claim 1, wherein the memory cells comprise carbon cells.

17. The integrated circuit according to claim 1, wherein the memory cells comprise transition metal oxide cells.

18. A means for testing a memory means for storing data, the means for testing being operable in a memory means testing mode, in which testing signals are applied to the memory means, wherein strengths and durations of the testing signals at least partly differ from strengths and durations of programming signals or sensing signals used for programming and sensing memory state of the memory means.

19. A memory module comprising at least one integrated circuit comprising a plurality of memory cells, the integrated circuit being operable in a memory cell testing mode in which testing signals are applied to the memory cells, wherein strengths and durations of the testing signals at least partly differ from strengths and durations of programming signals or sensing signals used for programming and sensing memory states of the memory cells.

20. The memory module according to claim 19, wherein the memory module is stackable.

21. A method of operating an integrated circuit comprising a plurality of memory cells, the method comprising applying testing signals to the memory cells, wherein strengths and durations of the testing signals at least partly differ from strengths and durations of programming signals or sensing signals used for programming and sensing memory states of the memory cells.

22. The method according to claim 21, wherein the testing signals are generated outside the integrated circuit and then supplied to the integrated circuit.

23. The method according to claim 21, further comprising supplying triggering signals that trigger the integrated circuit to generate testing signals.

24. The method according to claim 21, wherein the memory cells comprise resistivity changing memory cells, wherein a select device is assigned to each resistivity changing memory cell.

25. The method according to claim 24, wherein the resistivity changing memory cells are simultaneously set to a common resistance value by applying respective testing voltages or testing currents to the resistivity changing memory cells.

26. The method according to claim 25, wherein the resistivity changing memory cells are set to a common resistance value by applying a constant testing current or constant testing voltage to each resistivity changing memory cells for a period of time that is larger than a period of time used for reading or programming the memory states of the resistivity changing memory cells.

27. The method according to claim 26, wherein the common resistance value of the resistivity changing memory cells is controlled by using the select devices as voltage divider.

28. A method of operating a plurality of memory cells, the method comprising applying testing signals to the memory cells, wherein strengths and durations of the testing signals at least partly differ from strengths and durations of programming signals or sensing signals used for programming and sensing memory states of the memory cells.

29. A computer program product configured to perform, when being carried out on a computing device, a method of operating an integrated circuit comprising a plurality of memory cells, the method comprising applying testing signals to the memory cells, wherein strengths and durations of the testing signals at least partly differ from strengths and durations of programming signals or sensing signals used for programming and sensing memory states of the memory cells.

30. A method of manufacturing an integrated circuit comprising a plurality of memory cells, the method comprising:
providing a lower part of a circuit housing;
providing an integrated circuit on the lower part of the circuit housing;
testing the integrated circuit by supplying testing signals or triggering signals that cause the integrated circuit to generate testing signals to testing terminals that are coupled to the integrated circuit and that are provided on the lower part of the circuit housing; and
providing an upper part of the circuit housing on the integrated circuit such that the testing terminals are not accessible for a user using the integrated circuit.

31. An electronic test system, comprising:
control circuitry;
at least one input device coupled to said control circuitry;
at least one output device coupled to said control circuitry; and
an integrated circuit coupled to said control circuitry, the integrated circuit comprising a plurality of memory cells, the integrated circuit being operable in a memory cell testing mode in which testing signals are applied to the memory cells, wherein strengths and durations of the testing signals at least partly differ from strengths and durations of programming signals or sensing signals used for programming and sensing memory states of the memory cells.
